(19) United States
(12) Patent Application Publication
(10) Pub. No.: US 2008/0049531 A1
(43) Pub. Date: Feb. 28, 2008

(54) Memory arrangement and method for operating such a memory arrangement

(76) Inventor: Michael Kund, Tuntenhausen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 10/577,881

(22) PCT Filed: Oct. 27, 2004
(86) PCT No.: PCT/DE04/02396

§ 371 Date: Jan. 25, 2007

(30) Foreign Application Priority Data
Oct. 28, 2003 (DE) 103 50 168.1

(51) Int. Cl. G11C 7/00

(52) U.S. Cl. 365/222

(57) ABSTRACT

A memory arrangement and method of operating a memory arrangement is disclosed. In one embodiment of the memory arrangement according to the invention, rewritable memory cells are arranged at crossovers between word lines and bit lines, said memory cells being configured in such a manner that the information stored in them is essentially read out in a nondestructive manner. According to the invention, the memory arrangement has a flag cell either for each word line or for each bit line, said flag cell being able to store an item of information that indicates whether at least one of the memory cells either along the respective word line or along the respective bit line has been subjected to a reading operation since a basic state occurred.

### FIELD OF INVENTION

The present invention relates to a memory arrangement and to a method for operating a memory arrangement.

### BACKGROUND

Memory arrangements of the generic type are known, for example, in the form of semiconductor memory chips of the SRAM type or of one of the different rewritable ROM types such as EAROM, EPROM, EEPROM, flash memories etc. All of these chip types which certainly contain, as fundamental components, semiconducting materials such as, for example, silicon have the feature in common that the information stored in them is read out in a nondestructive manner, i.e., the information stored in them is also retained in them during the reading-out operation (in contrast to this, stored information is read out from DRAM memory arrangements in a destructive manner, thus resulting in the information that has been read out having to be written back again to the affected memory cells immediately after it has been read out).

As the miniaturization of the structures of integrated circuits advances and thus also as the miniaturization of the structures of memory arrangements of the generic type advances, an attempt has recently been made to provide memory arrangements whose storage mechanism is no longer based on the storage mechanisms known from semiconductor memories but rather on other storage mechanisms. Examples of such other storage mechanisms which are already generally known are, for example, the ferroelectric type (for example FeRAM) and the magnetic type (for example MRAM). In addition, however, research is also being carried out on memory types which are still largely unknown nowadays: for example, part 2 of the article “Die Zukunft des Speichers [The future of memory]” was available to the general public on the Internet on 13 Oct. 2003 and can be found using the address “www.elektroniknet.de/topics/bauelemente/fachthemen/2002/020223”.

Said article referred to polymer-based FeRAMs and to an “Ovonics Unified Memory OUM” as future new memory technologies. In addition, pages 118 to 123 of the journal “Elettronica Oggi 316”, October 2002 issue, presented a new storage mechanism having future prospects, namely an electrochemical memory using PMC technology (PMC=Programmable Metallization Cell). However, it can be expected in at least some of these storage mechanisms that, in the case of appropriately designed memory arrangements, although reading operations can be effected in a largely nondestructive manner, a certain degree of (quantitative) reduction in the information contained in the affected memory cells, which is caused by the reading-out operation, cannot be avoided. As a result, when repeatedly reading out from one and the same memory cell, the information stored in this memory cell will quantitatively decrease even if it has a digital character, which is generally referred to as degradation. It can thus be foreseen that, after being frequently read out, the amount of information contained in such a memory cell will then have decreased overall to such an extent that this information, during further reading-out operations, will no longer be able to be distinguished, by an evaluation device, from an item of information having the opposite logical content, with the result that read errors will appear.

A technically obvious solution to this problem, which is simple to implement, could be to configure each reading operation in such a manner that it is directly followed by a rewriting operation, with the result that an item of information that is read out from a memory cell in this manner is immediately written back to the same memory cell again, so that, in quantitative terms, it is fully available again for further reading operations on account of the associated signal amplification there. Therefore, such memory arrangements would need to be configured and operated in accordance with the DRAM semiconductor memories which are known everywhere. However, it is also probably reasonable that a rewriting operation, as described above, needs time which in turn would slow down the operation of corresponding memory arrangements to an extent felt to be unacceptable by the user.

For these and other reasons, there is a need for the present invention.

### SUMMARY

The present invention configures memory arrangements of the generic type in such a manner that a quantitative reduction in information stored in a memory cell, which is caused by repeatedly reading out the information, is prevented at least to such an extent that no read errors can arise as a result of further reading-out operations. The present invention also provides a corresponding operating method.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

The invention will be explained in more detail below with reference to a drawing.

FIGS. 1 to 3 illustrates different embodiments of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

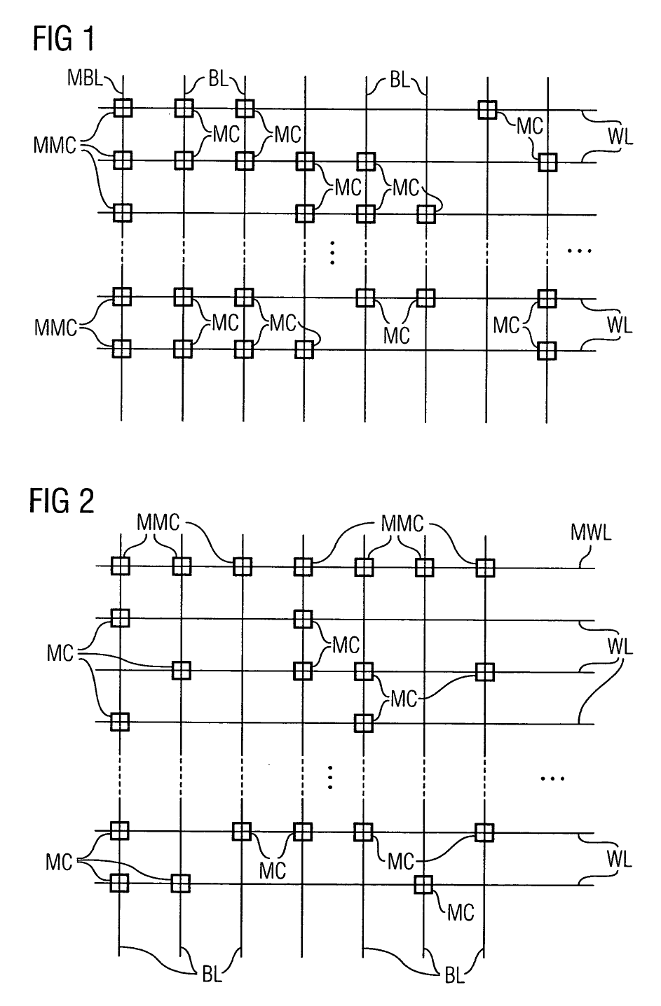

FIG. 1 illustrates part of a first embodiment of the present invention. It is assumed to be implemented in an individual memory chip. As is generally customary, this embodiment has rewritable memory cells MC which are arranged along word lines WL and bit lines BL, namely at crossovers between the word lines WL and the bit lines BL. The memory cells MC are of a type in which the information stored in them is read out in a largely nondestructive manner. In the case of memory arrangements which are customary nowadays, these may therefore be, for example, semiconductor memories of the abovementioned ROM types or of the static RAM type (SRAM). However, they may also be memory arrangements having storage materials and storage principles which will only gain economic importance in the future. One example of these which may be mentioned, as representative of other possible ways of storing information, are memory arrangements whose storage principle is based on the fact that, when a suitable voltage is applied, a solid electrolyte causes metal ions to migrate within an otherwise insulating electrolyte, with the result that, depending on whether or not a metallically conductive path is formed in this case, a different resistance value is obtained for the solid electrolyte, said resistance value being a synonym for the type of information stored (“logical 0” or “logical 1”).

In the case of this first embodiment, the invention now provides for another additional memory cell, namely a so-called flag cell MMC, to be arranged along each word line WL. Said flag cell is preferably of the same memory cell type as the memory cells MC. In particular, it should likewise be of the type that allows an item of information stored in it to be read out in a largely nondestructive manner. In this case, it is also advantageous if it is a memory cell of the nonvolatile type, so that information stored in it is also retained when the supply voltage is switched off. The flag cells MMC can be addressed via the respective word lines WL and via a flag bit line MBL.

When started up for the first time or else after a reset operation (will also be described), these flag cells MMC have a given basic state, i.e., a predetermined type of information is stored in the form of a standard value (either “logical 0” or “logical 1”). Whenever a read access operation to a memory cell MC is then carried out during subsequent operation of the memory arrangement, an item of information that is complementary to the abovementioned standard value is written, according to the invention, to that flag cell MMC which is connected to the same word line WL as the memory cell MC which has been addressed for reading purposes. The content of each flag cell MMC, i.e. the information stored in it, thus always reflects whether at least one of the memory cells MC which are arranged along that word line WL which is associated with the flag cell MMC under consideration has been subjected to a read access operation at least once.

The method according to the invention now provides for memory cells MC, which are arranged along a word line WL whose associated flag cell MMC has a memory content (can be determined by reading out the information stored in the flag cell MMC) which is complementary to the standard value, to be (occasionally) subjected to a refresh operation. As is known, during a refresh operation which is certainly known as such from the operation of dynamic semiconductor memories (DRAM), information stored in the memory cells which are to be refreshed is read out and is written back to the affected memory cells again (usually still in the same read cycle), the signals which represent this information also usually being amplified to their original value using the sense amplifiers which are assigned to the memory cells to be refreshed.

This effect whereby an item of information (whose signal has been amplified) is written back during a refresh operation is advantageously used in this case to make it possible for an item of information, which is stored in the memory cells MC and which, despite, on the one hand, being able to be read out as such in a largely nondestructive manner, has undergone a certain amount of degradation during repeated reading-out operations, to be returned to its (in quantitative terms) original value again. This makes it possible to avoid the amount of stored information, the amount of which is certainly assumed to decrease somewhat with each reading operation, becoming so small, sometime after being frequently read out, that it can no longer be detected as such by the associated sense amplifier, which is certainly usually configured as a differential amplifier, with the result that a read error arises.

The fact that such a refresh operation takes place only occasionally affords the advantage that considerably less time and energy need to be expended for this than if the information that has been read out were to be written back after each reading operation, as already described at the outset as a theoretical possibility. In addition, the considerably smaller amount of energy expended is also based on the fact that only the memory cells MC along those word lines WL along which the content of memory cells MC has also actually been previously read out are subjected to the refresh operation, which contrasts with the refresh operations which generally, i.e., compulsorily, take place in dynamic semiconductor memories (DRAM). In an analogous manner, these advantages also apply to the further operating method which will also be described later.

In the case of this operating method (and in the operating method which will also be described below), it is advantageous to reset the information stored in the flag cells MMC that initiate the refresh operation to the abovementioned standard value during the refresh operation or after the latter. It is also expedient to render the process of carrying out a refresh operation dependent on a further event that occurs or on a further criterion. Such a criterion may be, for example, a signal which is supplied to the memory arrangement and indicates that a control circuit, if appropriate also a processor, to which the memory arrangement according to the invention is connected is currently in the quiescent state. In such a case, the refresh operation does not give rise to any loss of time since the memory arrangement would otherwise not be operated actively in this period of time. Other criteria may also be (this list is only exemplary, not conclusive) the operation of switching on a device which contains the memory arrangement according to the invention, the switching-on operation giving rise to a special signal which is generally referred to as a “power-on signal” and is directly or indirectly supplied to the memory arrangement according to the invention, or the operation of charging a device which contains the memory arrangement according to the invention. In the latter case, a signal which then initiates the refresh operation may be derived, for example, from the fact that a charging current flows.

FIG. 2 illustrates another advantageous embodiment of the present invention: in this case, the flag cells MMC which are already known, in principle, from the first embodiment are arranged along the bit lines BL. In this case, the flag cells MMC can be addressed via the respective bit line BL and via a flag word line MWL that is assigned to the respective flag cell MMC. The function of these flag cells MMC and their associated operating method correspond to those already described above with the proviso that, in this case, a refresh operation is carried out only with respect to those memory cells MC which are arranged along a bit line BL with respect to which memory cells MC have previously been read. Information which indicates whether a reading operation has been carried out is also written to a flag cell MMC only with respect to those memory cells MC which are arranged along the bit line BL that is associated with a respective flag cell MMC.

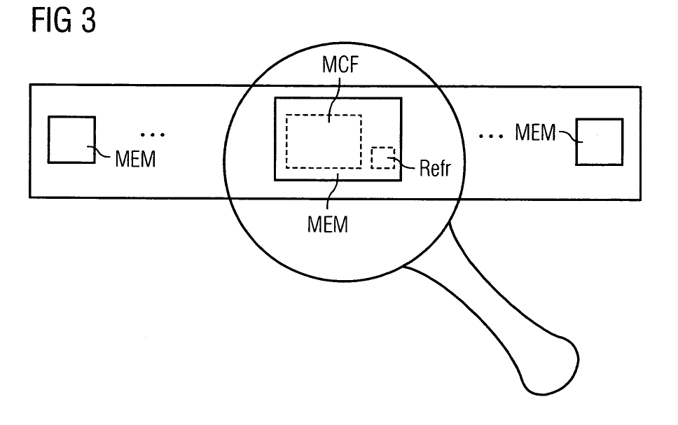

FIG. 3 illustrates a third embodiment of the present invention. In this case, the memory arrangement according to the invention is implemented using a plurality of memory chips MEM which are functionally assigned to one another. This is the case, for example, in the memory modules which are generally known as such. FIG. 3 illustrates such a memory module. Memory modules are usually driven by means of control circuits which are often referred to as controllers (not illustrated here). These control circuits may, for example, generate the abovementioned signals, which can generally be referred to as a “further event” and as such trigger the process of carrying out refresh operations, and supply said signals to the respective connected memory chips MEM. This embodiment also uses an individual memory chip MEM, which is symbolically shown on an enlarged scale using a magnifying glass, to illustrate that the individual memory chips MEM can contain, in addition to their memory cell array MCF, a so-called refresh device Refr which initiates and carries out a specifically desired refresh operation. The memory arrangements according to the first two embodiments of the present invention, in which the memory arrangement is equal to one memory chip MEM, may also have such a refresh device Refr. However, it is also conceivable for such a refresh device Refr to be outside the memory arrangement, for example inside the abovementioned control circuit.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1-12. (canceled)

13. A memory arrangement comprising:
a plurality of rewriteable memory cells arranged at crossovers between word lines and bit lines, wherein the memory cells are configured such a that the information stored in the memory cells is read out in a nondestructive manner; and
wherein the memory arrangement has a flag cell either for each word line or for each bit line, the flag cell being able to store an item of information that indicates whether at least one of the memory cells either along the respective word line or along the respective bit line has been subjected to a reading operation since a basic state occurred.

14. The memory arrangement as claimed in claim 13, comprising wherein the flag cells are of the same memory cell type as the memory cells.

15. The memory arrangement as claimed in claim 14, comprising wherein the flag cells are of a memory cell type in which the stored information can be read out in a nondestructive manner.

16. The memory arrangement as claimed in claim 13, comprising wherein the flag cells are of a memory cell type in which the stored information can be read out in a nondestructive manner.

17. The memory arrangement as claimed in claim 13, comprising wherein the flag cells are of the nonvolatile type.

18. The memory arrangement as claimed in claim 13, comprising wherein the memory arrangement is an individual memory chip.

19. The memory arrangement as claimed in claim 13, comprising wherein the memory arrangement is a plurality of memory chips that are assigned to one another.

20. The memory arrangement as claimed in claim 13, comprising wherein the memory arrangement has a refresh device for carrying out a refresh operation.

21. A method for operating a memory arrangement having rewritable memory cells which are arranged at crossovers between word lines and bit lines, in which arrangement the memory cells comprising:
reading out information stored in the memory cells in a nondestructive manner; and subjecting those memory cells which are arranged either along a word line or along a bit line along which at least one reading operation has previously taken place, to a refresh operation.

22. The method as claimed in claim 21, comprising:
storing the occurrence of a reading operation as such as information in a flag cell that is arranged either along a word line that is affected by the reading operation or along a bit line that is affected by the reading operation.

23. The method as claimed in claim 21, comprising:
resetting the information stored in the affected flag cells to a standard value when carrying out the refresh operation.

24. The method as claimed in claims 21, comprising:
triggering the carrying-out of the refresh operation by another given event.

25. A memory arrangement comprising:
rewritable memory cells which are arranged at crossovers between word lines and bit lines, in which arrangement the memory cells are configured in such a manner that the information stored in the memory cells is read out in a nondestructive manner;
a refresh device for carrying out a refresh operation;
a flag cell either for each word line or for each bit line, the flag cell being able to store an item of information that indicates whether at least one of the memory cells either along the respective word line or along the respective bit line has been subjected to a reading operation since a basic state occurred; and
wherein the refresh device is designed in such a manner that, for each flag cell, it carries out a refresh operation, in a manner dependent on the information stored in the flag cell, for those memory cells which are arranged along the word line or bit line associated with the flag cell.

26. The memory arrangement as claimed in claim 25, comprising wherein the flag cells are of a memory cell type in which the stored information can be read out in a nondestructive manner.

27. The memory arrangement as claimed in claim 26, comprising wherein the flag cells are of the nonvolatile type.

28. The memory arrangement as claimed in claim 27, comprising wherein the memory arrangement is an individual memory chip.

29. The memory arrangement as claimed in claim 28, comprising wherein the memory arrangement is a plurality of memory chips that are assigned to one another.

30. The memory arrangement as claimed in claim 29, comprising wherein the memory arrangement has a refresh device for carrying out a refresh operation.

31. The memory arrangement as claimed in claim 13, comprising wherein the flag cells are of the same memory cell type as the memory cells.

32. The memory arrangement as claimed in claim 14, comprising wherein the flag cells are of a memory cell type in which the stored information can be read out in a nondestructive manner.

33. A memory arrangement comprising:
a plurality of rewriteable memory cells arranged at crossovers between word lines and bit lines, wherein the memory cells are configured such a that the information stored in the memory cells is read out in a nondestructive manner; and
means for providing a flag cell either for each word line or for each bit line, the flag cell means being able to store an item of information that indicates whether at least one of the memory cells either along the respective word line or along the respective bit line has been subjected to a reading operation since a basic state occurred.
